(19) United States
(12) Patent Application Publication
(10) Pub. No.: US 2023/0396040 A1
(43) Pub. Date: Dec. 7, 2023

(54) SEMICONDUCTOR LASER EPITAXIAL STRUCTURE

(71) Applicant: VISUAL PHOTONICS EPITAXY CO., LTD., Taoyuan City (TW)

(72) Inventors: Van-Truong DAI, Taoyuan City (TW); Yu-Chung CHIN, Taoyuan City (TW); Chao-Hsing HUANG, Taoyuan City (TW); Chien-hung PAN, Taoyuan City (TW); Chun-huang WU, Taoyuan City (TW)

(21) Appl. No.: 18/307,812

(22) Filed: Apr. 27, 2023

(30) Foreign Application Priority Data
Apr. 27, 2022 (TW) 111115974

(51) Int. Cl. H01S 5/50; H01S 5/183; H01S 5/34

(52) U.S. Cl. CPC H01S 5/50; H01S 5/18361; H01S 5/3416

(57) ABSTRACT

A semiconductor laser epitaxial structure includes a horizontal cavity configured to generate an optical field distribution, a grating layer located within the optical field distribution, a first semiconductor optical amplifier disposed between a light-emitting surface of the semiconductor laser epitaxial structure and the horizontal cavity, and a first tunnel junction layer disposed between the horizontal cavity and the first semiconductor optical amplifier. The grating layer is configured to convert a horizontal light to a vertical light. The semiconductor laser epitaxial structure does not require alignment, the yield rate of manufacturing the semiconductor laser is increased, and the manufacturing cost and manufacturing processes can be reduced.

### RELATED APPLICATIONS

This application claims priority to Taiwanese Application Ser. No. 111115974, filed Apr. 27, 2022, which is herein incorporated by reference.

### BACKGROUND

### Field of Invention

The present disclosure relates to an epitaxial structure, particularly for fabricating semiconductor laser with small divergence angle and high optical output power.

### Description of Related Art

Semiconductor laser includes vertical cavity surface emitting laser (VCSEL) or edge emitting laser (EEL).

The advantages of EEL include high optical output power. However, EEL suffers from wide divergence angle, which makes it difficult to couple with an optical fiber. On the other hand, the VCSEL has a small divergence angle and is easy to couple with to an optical fiber. However, VCSEL suffers from low optical output power, which limits light propagation distance.

### SUMMARY

According to some embodiments of the disclosure, a semiconductor laser epitaxial structure includes a horizontal cavity configured to generate an optical field distribution, a grating layer located within the optical field distribution, a first semiconductor optical amplifier disposed between a light-emitting surface of the semiconductor laser epitaxial structure and the horizontal cavity, and a first tunnel junction layer disposed between the horizontal cavity and the first semiconductor optical amplifier. The grating layer is configured to convert a horizontal light to a vertical light.

According to some embodiments of the disclosure, a semiconductor laser epitaxial structure includes a horizontal cavity configured to generate an optical field distribution, a grating layer located within the optical field distribution, a first semiconductor optical amplifier disposed between a non-light-emitting surface of the semiconductor laser epitaxial structure and the horizontal cavity, a first reflection unit disposed between the non-light-emitting surface and the first semiconductor optical amplifier, and a first tunnel junction layer disposed between the horizontal cavity and the first semiconductor optical amplifier to electrically connect the horizontal cavity and the first semiconductor optical amplifier. The grating layer is configured to convert a horizontal light to a vertical light.

Although the resonant direction of the laser in the horizontal cavity is parallel to the epitaxial plane, the amplified laser is emitted in a direction perpendicular to the epitaxial plane by virtue of the embodiments thereof. The divergence angle of semiconductor laser fabricated using the embodiments thereof can be as small as about 1 to 3 degrees or even smaller. The divergence angle of semiconductor laser is much less than that of VCSEL which have the divergence angle in about decades degrees. In addition, the optical output power of semiconductor laser is also higher than that of VCSEL.

The semiconductor laser epitaxial structure in this disclosure can be utilized to fabricate the semiconductor laser for applications such as sensing, 3D sensing technology, light detection and ranging (LiDAR), or optical communication.

Additionally, as the semiconductor laser epitaxial structure does not require alignment, the yield rate of manufacturing the semiconductor laser is increased, and the manufacturing cost and manufacturing processes can be reduced.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

### IN THE DRAWINGS

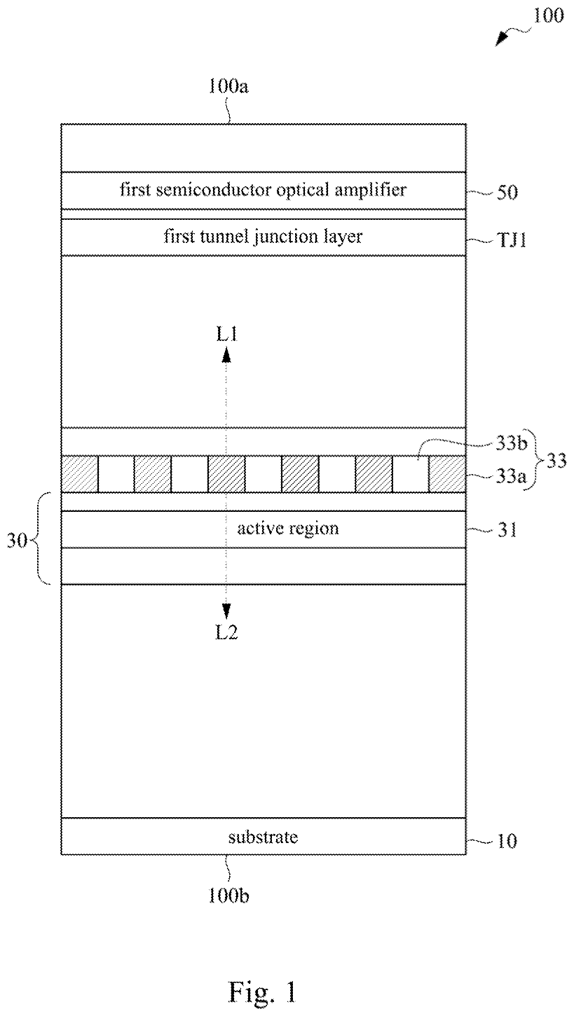

FIG. 1 is a schematic view of a semiconductor laser epitaxial structure of a first embodiment of the disclosure;

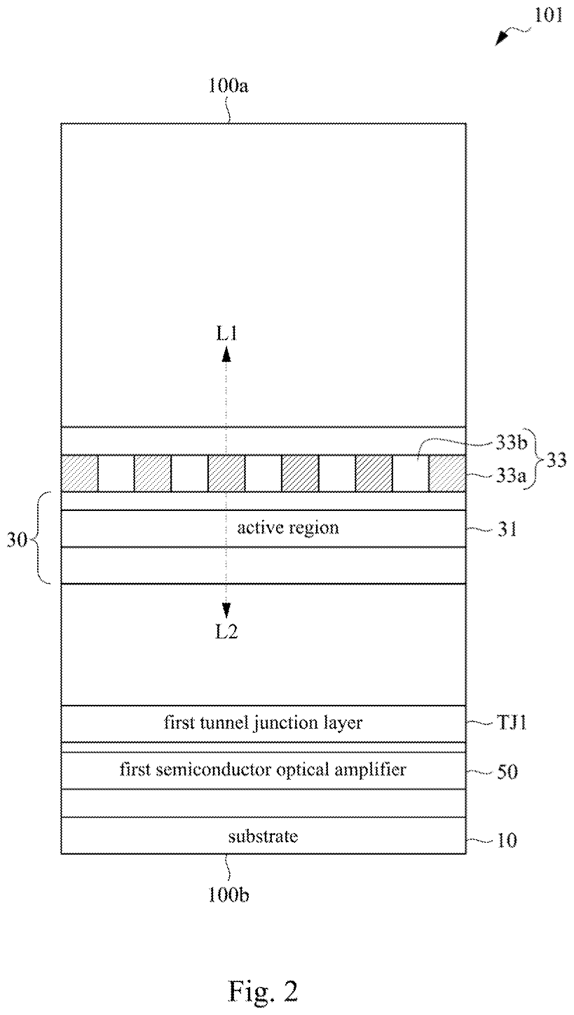

FIG. 2 is a schematic view of a semiconductor laser epitaxial structure of a second embodiment of the disclosure;

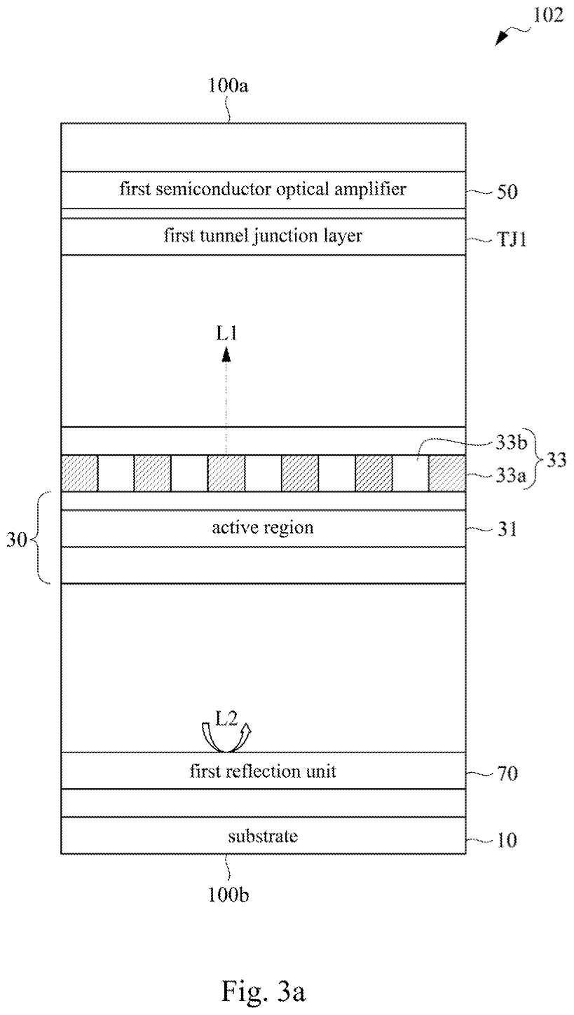

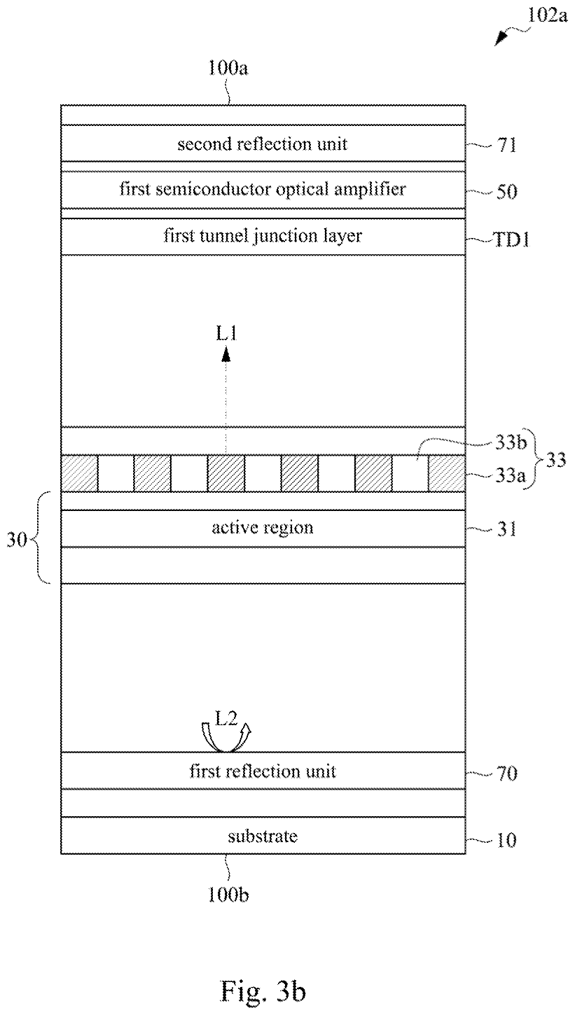

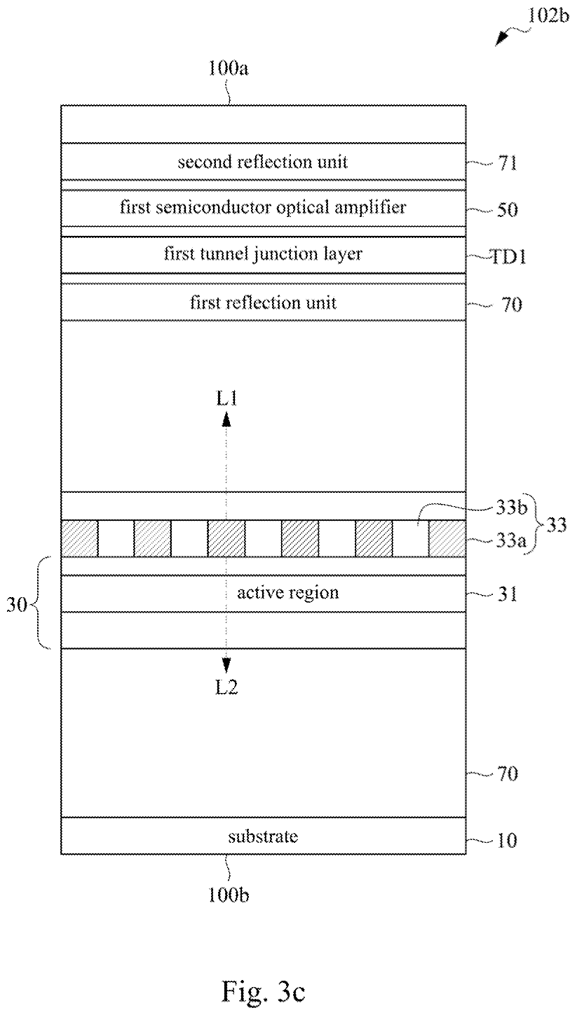

FIG. 3a is a schematic view of a semiconductor laser epitaxial structure of a third embodiment of the disclosure;

FIG. 3b is a schematic view of a variation of the third embodiment of the disclosure;

FIG. 3c is a schematic view of another variation of the third embodiment of the disclosure;

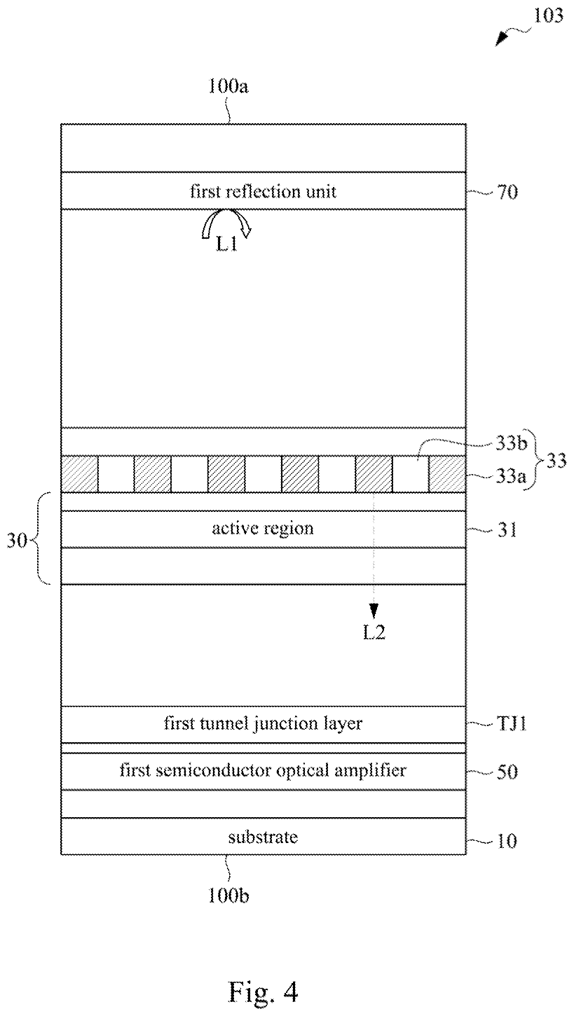

FIG. 4 is a schematic view of a fourth embodiment of a semiconductor laser epitaxial structure of the disclosure;

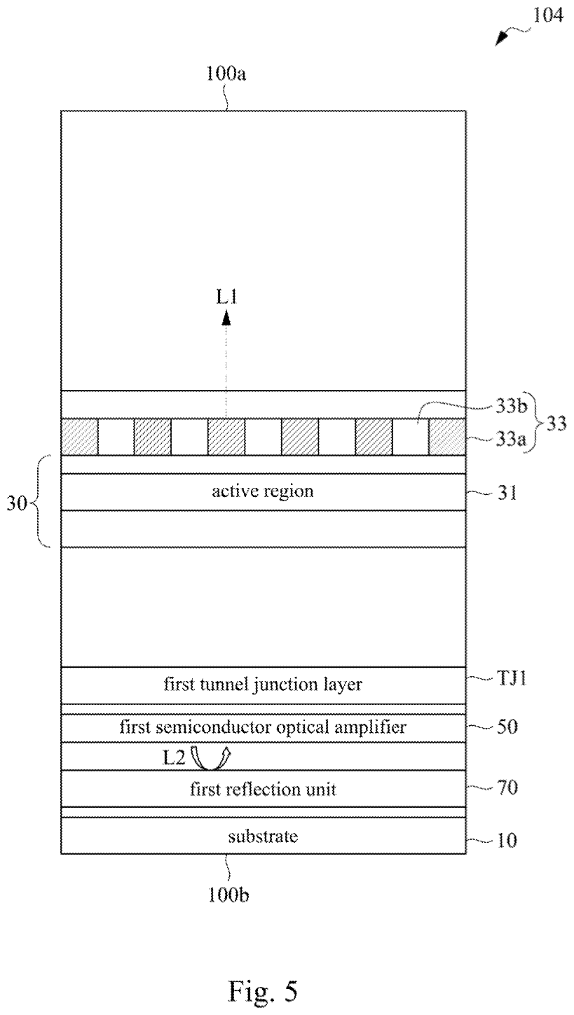

FIG. 5 is a schematic view of a fifth embodiment of a semiconductor laser epitaxial structure of the disclosure;

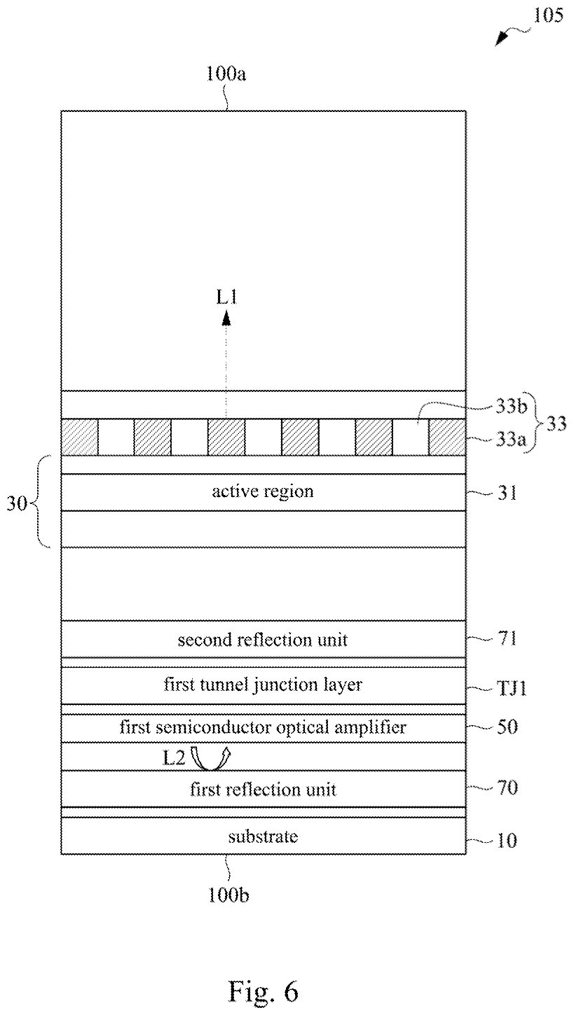

FIG. 6 is a schematic view of a sixth embodiment of a semiconductor laser epitaxial structure of the disclosure;

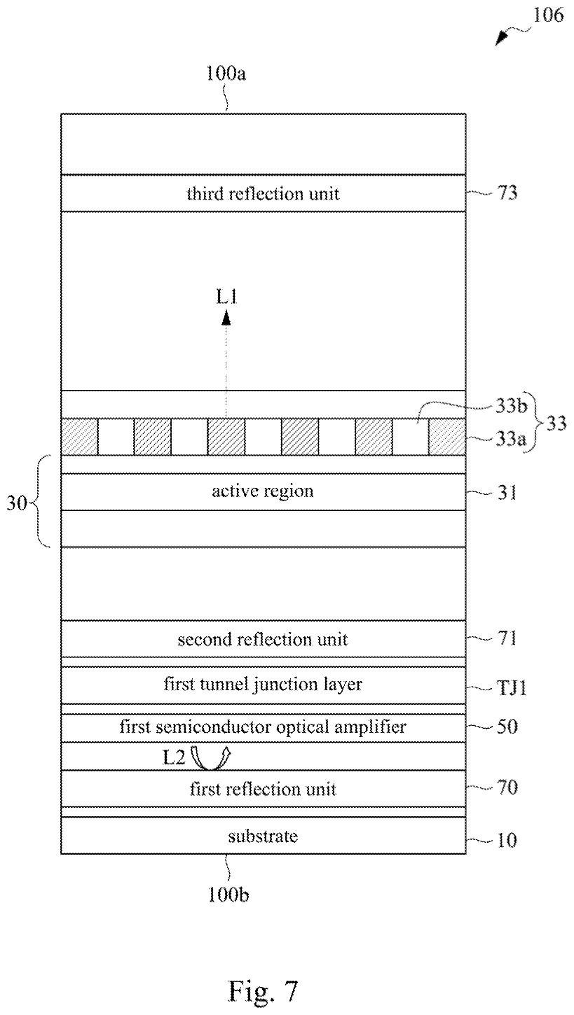

FIG. 7 is a schematic view of a seventh embodiment of a semiconductor laser epitaxial structure of the disclosure;

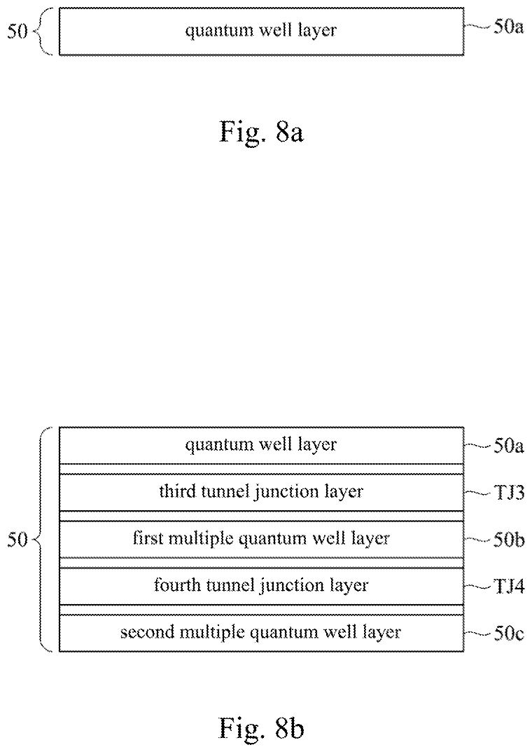

FIG. 8a is a schematic view illustrating that the first semiconductor optical amplifier includes one quantum well layer according to some embodiments of the disclosure;

FIG. 8b is a schematic view illustrating that the first semiconductor optical amplifier includes plural multiple quantum well layer according to some embodiments of the disclosure;

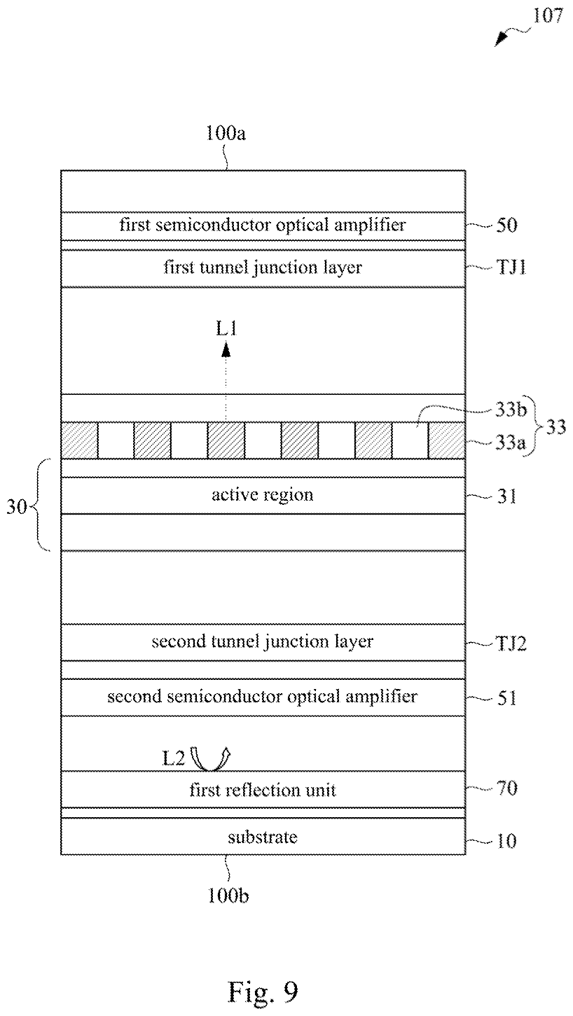

FIG. 9 is a schematic view of an eighth embodiment of a semiconductor laser epitaxial structure of the disclosure; and

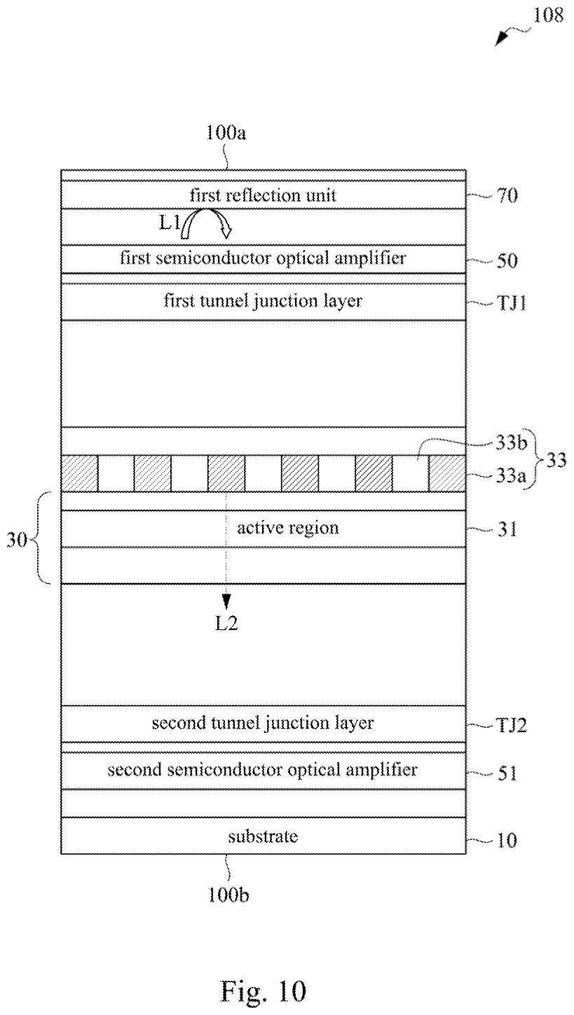

FIG. 10 is a schematic view of a ninth embodiment of a semiconductor laser epitaxial structure of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

Specific examples of components and arrangements are described below to simplify the present disclosure. These are, of course, merely examples and they are not intended to limit the scope of the present disclosure. In the present disclosure, for example, when a layer formed above or on another layer, it may include an exemplary embodiment in which the layer is in direct contact with the another layer, or it may include an exemplary embodiment in which other devices or epitaxial layers are formed between thereof, such that the layer is not in direct contact with the another layer. In addition, repeated reference numerals and/or notations may be used in different embodiments, these repetitions are only used to describe some embodiments simply and clearly, and do not represent a specific relationship between the different embodiments and/or structures discussed.

Further, spatially relative terms, such as “underlying,” “below,” “lower,” “overlying,” “above,” “upper” and the like, may be used herein for ease of description to describe one device or feature's relationship to another device(s) or feature(s) as illustrated in the figures and/or drawings. The spatially relative terms are intended to encompass different orientations of the device in use or operation in addition to the orientation depicted in the figures and/or drawings.

Moreover, certain terminology has been used to describe embodiments of the present disclosure. For example, the terms “one embodiment,” “an embodiment,” and “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment.

Furthermore, the particular features, structures or characteristics may be combined in any suitable manner in one or more embodiments of the present disclosure. Further, for the terms “including”, “having”, “with”, “wherein” or the foregoing transformations used herein, these terms are similar to the term “comprising” to include corresponding features.

In addition, a “layer” may be a single layer or a plurality of layers; and “a portion” of an epitaxial layer may be one layer of the epitaxial layer or a plurality of adjacent layers. Also, the semiconductor laser epitaxial structure also referred as epitaxial structure.

FIG. 1 is a schematic view of a semiconductor laser epitaxial structure of a first embodiment of the disclosure.

The semiconductor laser epitaxial structure 100 in FIG. 1 has a top surface 100a and a bottom surface 100b opposite to the top surface 100a, in which the top surface 100a is an upper surface of the epitaxial structure, and the bottom surface 100b is a lower surface of the substrate. The semiconductor laser epitaxial structure (hereafter also referred as epitaxial structure) in FIG. 1 is utilized to make a top-emitting semiconductor laser, therefore the top surface 100a is the light-emitting surface, and the bottom surface 100b is the non-light-emitting surface. The semiconductor laser epitaxial structure 100 includes a substrate 10, a horizontal cavity 30, a grating layer 33, a first semiconductor optical amplifier (SOA) 50, and a first tunnel junction layer TJ1.

As shown in FIG. 1, the horizontal cavity 30 includes an active region 31. The active region 31 includes one or more active layers. The active layer includes a quantum well layer or a multiple quantum well layers. The horizontal cavity 30 will generate an optical field distribution of horizontal light when the horizontal cavity 30 is excited by current or light. The “horizontal light” means that the resonant direction of the light generated by the horizontal cavity 30 is parallel to the top surface 100a (e.g. the epitaxial plane).

The grating layer 33 is disposed within the optical field distribution. The grating layer 33 is configured to convert the horizontal light to a vertical light whose direction is perpendicular to the top surface 100a. Because the optical field distribution of the horizontal cavity 30 is a Gaussian distribution, the edge of the optical field distribution may reach the layer(s) above or below the active region 31. Therefore, the grating layer 33 in FIG. 1 can be also disposed below the active region 31 based on actual requirements. Further, a portion of the vertical light, hereafter as a first light L1, is propagated to the top surface 100a (e.g. the light-emitting surface), and another portion of the vertical light, hereafter as a second light L2, is propagated to the bottom surface 100b.

The first SOA 50 is disposed between the grating layer 33 and the top surface 100a, and the first light L1 passes the first SOA 50. The first SOA 50 amplifies the first light L1. The first semiconductor optical amplifier 50 may include a quantum well layer, and the quantum well layer has many carriers. After the first light L1 passes the first semiconductor optical amplifier 50 including the quantum well layer, the carriers receive energy and generate vertical light having the same phase and the direction, and the first light L1 is amplified.

The first tunnel junction layer TJ1 is disposed between the horizontal cavity 30 and the first SOA 50. Preferably, the first SOA 50 and the first tunnel junction layer TJ1 are not located within the optical field distribution of the horizontal cavity 30 to avoid that the first SOA 50 is excited by the optical field distribution and generates horizontal light.

In some embodiments, an additional current can be applied to the first SOA 50, such that the first SOA 50 will be injected extra carriers, thereby enhancing the optical output power of the semiconductor laser.

FIG. 2 is a schematic view of a semiconductor laser epitaxial structure of a second embodiment of the disclosure. The semiconductor laser epitaxial structure 101 in FIG. 2 is utilized to make a bottom-emitting semiconductor laser, therefore the bottom surface 100b is the light-emitting surface, and the top surface 100a is the non-light-emitting surface.

The semiconductor laser epitaxial structure 101 of FIG. 2 includes the substrate 10, the horizontal cavity 30, the grating layer 33, the first SOA 50, and the first tunnel junction layer TJ1, in which the first tunnel junction layer TJ1 and the first SOA 50 are disposed on a light propagation path of the second light L2. More particularly, the first tunnel junction layer TJ1 and the first SOA 50 are disposed between the substrate 10 and the horizontal cavity 30, in which the first tunnel junction layer TJ1 is disposed between the horizontal cavity 30 and the first SOA 50 to electrically connect the horizontal cavity 30 and the first SOA 50.

FIG. 3a is a schematic view of a semiconductor laser epitaxial structure of a third embodiment of the disclosure. The semiconductor laser epitaxial structure 102 of FIG. 3a is formed by adding a first reflection unit 70 in the epitaxial structure 100 of FIG. 1. The first reflection unit 70 is disposed on a light propagation path of the second light L2. For example, as shown in FIG. 3a, the first reflection unit 70 is disposed between the horizontal cavity 30 and the substrate 10. The second light L2 is reflected by the first reflection unit 70 and is propagated towards the top surface 100a. Also, the second light L2 is amplified by the first SOA 50 and is emitted from the top surface 100a. As a result, the second light L2 is amplified, and the optical output power of the semiconductor laser can be further improved.

FIG. 3b is a schematic view of a variation of the third embodiment of the disclosure, and FIG. 3c is a schematic view of another variation of the third embodiment of the disclosure. Both the semiconductor laser epitaxial structure 102a of FIG. 3b and the semiconductor laser epitaxial structure 102b of FIG. 3c are formed by adding a second reflection unit 71 in the epitaxial structure 102 of FIG. 3a. As shown in the embodiments of FIG. 3b and FIG. 3c, the second reflection unit 71 is disposed between the first SOA 50 and the top surface 100a (e.g. the light-emitting surface), and the first reflection unit 70 is disposed between the horizontal cavity 30 and the bottom surface 100b (referring to FIG. 3b) or is disposed between the horizontal cavity 30 and the first SOA 50 (referring to FIG. 3c). By arranging two reflection units below and above, respectively, the first semiconductor optical amplifier, the laser light can pass through the first semiconductor optical amplifier back and forth to achieve amplifications of one or more times. Basically, the reflection unit closest to the non-light-emitting surface has the maximum reflective index.

FIG. 4 is a schematic view of a fourth embodiment of a semiconductor laser epitaxial structure of the disclosure. The semiconductor laser epitaxial structure 103 of FIG. 4 is formed by adding a first reflection unit 70 in the epitaxial structure 101 of FIG. 2. The first reflection unit 70 is utilized to reflect the first light L1 towards the bottom surface 100b (e.g. the light-emitting surface). The first light L1 is amplified by the first SOA 50, and the amplified first light L1 is emitted vertically from the bottom surface 100b (e.g. the light-emitting surface).

FIG. 5 is a schematic view of a fifth embodiment of a semiconductor laser epitaxial structure of the disclosure. The semiconductor laser epitaxial structure 104 of FIG. 5 is utilized to fabricate a top-emitting semiconductor laser. As shown in FIG. 5, the semiconductor laser epitaxial structure 104 includes the substrate 10, the horizontal cavity 30, the grating layer 33, the first SOA 50, the first tunnel junction layer TJ1, and the first reflection unit 70. This embodiment is utilized in a top-emitting semiconductor laser, therefore, the top surface 100a is the light-emitting surface, and the bottom surface 100b is the non-light-emitting surface.

The first SOA 50, the first tunnel junction layer TJ1, and the first reflection unit 70 are disposed on the light propagation path of the second light L2. As shown in FIG. 5, the first SOA 50, the first tunnel junction layer TJ1, and the first reflection unit 70 are disposed between the substrate 10 and the horizontal cavity 30. Similar to the previous embodiments, the first SOA 50 and the first tunnel junction layer TJ1 are spaced apart from the horizontal cavity 30.

FIG. 6 is a schematic view of a sixth embodiment of a semiconductor laser epitaxial structure of the disclosure. FIG. 7 is a schematic view of a seventh embodiment of a semiconductor laser epitaxial structure of the disclosure. The epitaxial structure 105 of FIG. 6 is formed by adding a second reflection unit 71 in the epitaxial structure 104 of FIG. 5, and the epitaxial structure 106 of FIG. 7 is formed by adding a third reflection unit 73 in the epitaxial structure 105 of FIG. 6. In the embodiments of FIG. 6 and FIG. 7, the first reflection unit 70 has the maximum reflective index, while the reflective index of the second reflection unit 71 and the third reflection unit 73 can be determined based on the actual requirements. By using such arrangement, there is a probability for the second light L2 to undergo amplification in the first SOA 50 once or multiple times, but it is preferable to avoid lasing, in order to approach maximum amplification of the second laser L2.

Preferably, the first reflection unit 70, the second reflection unit 71, and the third reflection unit 73 are distributed Bragg reflector layers.

FIG. 8a illustrates that the first SOA 50 includes a quantum well layer 50a or a multiple quantum well layer (not shown). FIG. 8b illustrates that the first SOA 50 may include at least one quantum well layer 50a, a first multiple quantum well layer 50b, and a second multiple quantum well layer 50c. The quantum well layer 50a and the first multiple quantum well layer 50b are electrically connected by a third tunnel junction layer TJ3, and the first multiple quantum well layer 50b and the second multiple quantum well layer 50c are electrically connected by a fourth tunnel junction layer TJ4.

FIG. 9 is a schematic view of an eighth embodiment of a semiconductor laser epitaxial structure of the disclosure. The semiconductor laser epitaxial structure 107 of FIG. 9 is formed by adding a second semiconductor optical amplifier 51, the second tunnel junction layer TJ2, and the first reflection unit 70 in the semiconductor laser epitaxial structure 100 of FIG. 1. While operating the semiconductor laser epitaxial structure 107, the first light L1 is amplified once, and the second light L2 having the vertical direction is amplified more than once. The amplified first light L1 and second light L2 are emitted vertically from the top surface 100a. Therefore, the top-emitting semiconductor laser using the structure of the semiconductor laser epitaxial structure 107 of FIG. 9 have high optical output power.

FIG. 10 is a schematic view of a ninth embodiment of a semiconductor laser epitaxial structure of the disclosure. The bottom surface 100b of the semiconductor laser epitaxial structure 108 of FIG. 10 is the light-emitting surface. The first light L1 is amplified at least twice, and the second light L2 is amplified once. Therefore, the semiconductor laser using the structure of the semiconductor laser epitaxial structure 108 of FIG. 10 have high optical output power.

In some embodiments, the first tunnel junction layer TJ1 or the second tunnel junction layer TJ2 is disposed at the smallest optical field for low optical absorption.

In some embodiments, the grating layer 33 includes a plurality of high-refractivity materials 33a and a plurality of low-refractivity materials 33b. The low-refractivity materials 33b include void, semiconductor materials, dielectric materials, or photonic crystals. The grating layer 33 is a one dimension period structure when the low-refractivity materials 33b are voids, semiconductor materials, or dielectric materials. Namely, the high-refractivity materials 33a and the low-refractivity materials 33b are alternatively arranged along the horizontal direction.

The grating layer 33 is a two dimension period structure when the low-refractivity films 33b are photonic crystals.

Although the present disclosure has been described in considerable detail with reference to certain embodiments thereof, other embodiments are possible. Therefore, the spirit and scope of the appended claims should not be limited to the description of the embodiments contained herein.

1. A semiconductor laser epitaxial structure, comprising;
a horizontal cavity configured to generate an optical field distribution;
a grating layer located within the optical field distribution, wherein the grating layer is configured to convert a horizontal light to a vertical light;
a first semiconductor optical amplifier disposed between a light-emitting surface of the semiconductor laser epitaxial structure and the horizontal cavity; and
a first tunnel junction layer disposed between the horizontal cavity and the first semiconductor optical amplifier.

2. The semiconductor laser epitaxial structure of claim 1, wherein the light-emitting surface is one of a top surface and a bottom surface of the semiconductor laser epitaxial structure, and another one of the top surface and the bottom surface of the semiconductor laser epitaxial structure is a non-light-emitting surface of the semiconductor laser epitaxial structure.

3. The semiconductor laser epitaxial structure of claim 2, further comprising a first reflection unit disposed between the non-light-emitting surface and the horizontal cavity.

4. The semiconductor laser epitaxial structure of claim 2, further comprising a second semiconductor optical amplifier, a second tunnel junction layer, and a first reflection unit, these are disposed between the non-light-emitting surface and the horizontal cavity, wherein the second tunnel junction layer is disposed between the second semiconductor optical amplifier and the horizontal cavity, and the first reflection unit is disposed between the non-light-emitting surface and the second semiconductor optical amplifier.

5. The semiconductor laser epitaxial structure of claim 2, further comprising:
a first reflection unit disposed between the non-light-emitting surface and the first semiconductor optical amplifier; and
a second reflection unit disposed between the first semiconductor optical amplifier and the light-emitting surface, wherein a reflective index of the first reflection unit is greater than a reflective index of the second reflection unit.

6. The semiconductor laser epitaxial structure of claim 5, wherein the first semiconductor optical amplifier, the first tunnel junction layer, the first reflection unit, or combinations thereof are not located within the optical field distribution.

7. The semiconductor laser epitaxial structure of claim 5, wherein the first reflection unit, the second reflection unit, or a combination thereof is a distributed Bragg reflector layer.

8. The semiconductor laser epitaxial structure of claim 1, wherein the first semiconductor optical amplifier, the first tunnel junction layer, or a combination thereof is not located within the optical field distribution.

9. The semiconductor laser epitaxial structure of claim 1, wherein the first semiconductor optical amplifier comprises a quantum well layer or a multiple quantum well layers.

10. The semiconductor laser epitaxial structure of claim 1, wherein the first semiconductor optical amplifier comprises two multiple quantum well layers and a second tunnel junction layer, and the second tunnel junction layer is disposed between the two multiple quantum well layers to electrically connect the two multiple quantum well layers the first semiconductor optical amplifier, the first tunnel junction layer, the first reflection unit, or combinations thereof are not located within the optical field distribution.

11. The semiconductor laser epitaxial structure of claim 1, wherein the grating layer is a one dimension period structure, the grating layer comprises a plurality of high-refractivity materials and a plurality of low-refractivity materials, and the low-refractivity materials comprise voids, semiconductor materials, or dielectric materials the first reflection unit, the second reflection unit, or a combination thereof is a distributed Bragg reflector layer.

12. The semiconductor laser epitaxial structure of claim 1, wherein the grating layer is a two dimension period structure, the grating layer comprises a plurality of high-refractivity materials and a plurality of low-refractivity materials, and the low-refractivity materials are photonic crystal.

13. A semiconductor laser epitaxial structure, comprising;
a horizontal cavity configured to generate an optical field distribution;
a grating layer located within the optical field distribution, wherein the grating layer is configured to convert a horizontal light to a vertical light;
a first semiconductor optical amplifier disposed between a non-light-emitting surface of the semiconductor laser epitaxial structure and the horizontal cavity;
a first reflection unit disposed between the non-light-emitting surface and the first semiconductor optical amplifier; and
a first tunnel junction layer disposed between the horizontal cavity and the first semiconductor optical amplifier to electrically connect the horizontal cavity and the first semiconductor optical amplifier.

14. The semiconductor laser epitaxial structure of claim 13, wherein the non-light-emitting surface is one of a top surface and a bottom surface of the semiconductor laser epitaxial structure, and another one of the top surface and the bottom surface of the semiconductor laser epitaxial structure is a light-emitting surface of the semiconductor laser epitaxial structure.

15. The semiconductor laser epitaxial structure of claim 14, further comprising a second semiconductor optical amplifier and a second tunnel junction layer, wherein the second semiconductor optical amplifier and the second tunnel junction layer are disposed between the horizontal cavity and the light-emitting surface, and the second tunnel junction layer is disposed between the second semiconductor optical amplifier and the horizontal cavity.

16. The semiconductor laser epitaxial structure of claim 13, wherein the first semiconductor optical amplifier, the first tunnel junction layer, or a combination thereof is not located within the optical field distribution.

17. The semiconductor laser epitaxial structure of claim 13, wherein the first semiconductor optical amplifier comprises a quantum well layer or a multiple quantum well layers.

18. The semiconductor laser epitaxial structure of claim 13, wherein the first semiconductor optical amplifier comprises two multiple quantum well layers and a second tunnel junction layer, and the second tunnel junction layer is disposed between the two multiple quantum well layers to electrically connect the two multiple quantum well layers.

19. The semiconductor laser epitaxial structure of claim 13, wherein the grating layer is a one dimension period structure, the grating layer comprises a plurality of high-refractivity materials and a plurality of low-refractivity materials, and the low-refractivity materials comprise voids, semiconductor materials, or dielectric materials.

20. The semiconductor laser epitaxial structure of claim 13, wherein the grating layer is a two dimension period structure, the grating layer comprises a plurality of high-refractivity materials and a plurality of low-refractivity materials, and the low-refractivity materials are photonic crystal.

21. The semiconductor laser epitaxial structure of claim 13, further comprising a second reflection unit disposed between the first semiconductor optical amplifier and the light-emitting surface, wherein a reflective index of the first reflection unit is greater than a reflective index of the second reflection unit.

22. The semiconductor laser epitaxial structure of claim 21, wherein the first reflection unit, the second reflection unit, or a combination thereof is a distributed Bragg reflector layer.
